(19) United States
(12) Patent Application Publication
(10) Pub. No.: US 2012/0152349 A1
(43) Pub. Date: Jun. 21, 2012

(54) JUNCTION BOX ATTACHMENT FOR PHOTOVOLTAIC THIN FILM DEVICES

(75) Inventors: Ting Cao, San Jose, CA (US); Burak Metin, San Jose, CA (US); Victor Duarte, Sunnyvale, CA (US); Eric Lee, San Jose, CA (US); Mustafa Pinarbasi, Morgan Hill, CA (US)

(73) Assignee: SoloPower, Inc., San Jose, CA (US)

(21) Appl. No.: 13/333,960

(22) Filed: Dec. 21, 2011

Related U.S. Application Data
(63) Continuation-in-part of application No. 12/972,367, filed on Dec. 17, 2010.
Application No. 12/972,367 is a continuation-in-part of application No. 13/219,484, filed on Aug. 26, 2011.

(51) Int. Cl. H01L 31/0203; H01L 31/18

(52) U.S. Cl. 136/259; 438/66; 257/E31.113

(57) ABSTRACT

A flexible solar cell assembly having solar cells that are positioned within a sealed module chamber. A sealed wiring chamber is positioned on an end of the sealed module chamber and is interposed between the sealed module chamber and a junction box. Wiring interconnecting the junction box to the solar cells in the sealed module chamber is routed through the sealed wiring chamber to inhibit water entry into the sealed module chamber via the wiring.

### RELATED APPLICATIONS

This application is related to U.S. application Ser. No. ______ (Atty Docket No. SPOW.001P1) entitled METHOD OF MANUFACTURING SOLAR MODULES and U.S. application Ser. No.______.

### BACKGROUND

1. Field of the Inventions

The aspects and advantages of the present inventions generally relate to apparatus and methods of photovoltaic or solar module design and fabrication and, more particularly, to roll-to-roll or continuous packaging techniques for flexible modules employing thin film solar cells.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

In standard CIGS as well as Si and amorphous Si module technologies, the solar cells can be manufactured on flexible conductive substrates such as stainless steel foil substrates. Due to its flexibility, a stainless steel substrate allows low cost roll-to-roll solar cell manufacturing techniques. In such solar cells built on conductive substrates, the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In standard silicon, CIGS and amorphous silicon cells that are fabricated on conductive substrates such as aluminum or stainless steel foils, the solar cells are not deposited or formed on the protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

Generally, the most common packaging technology involves lamination of circuits in transparent encapsulants. In a lamination process, in general, the electrically interconnected solar cells are covered with a transparent and flexible encapsulant layer. A variety of materials are used as encapsulants, for packaging solar cell modules, such as ethylene vinyl acetate copolymer (EVA), thermoplastic polyurethanes (TPU), polyolefins, and silicones. However, in general, such encapsulant materials are moisture permeable; therefore, they must be further sealed from the environment by a protective shell, which provides resistance to moisture transmission into the module package.

The nature of the protective shell determines the amount of water that can enter the package. The protective shell includes a front protective sheet through which light enters the module and a back protective sheet and optionally an edge sealant that is at the periphery of the module structure. The top protective sheet is typically transparent glass which is water impermeable. The back protective sheet may be a sheet of glass or a polymeric sheet of TEDLAR® (a product of DuPont) and polyeyhylene teraphthalate (PET). The back protective polymeric sheet may or may not have a moisture barrier layer in its structure such as a metallic film like an aluminum film. The edge sealant is a moisture barrier material that may be in the form of a viscous fluid which may be dispensed from a nozzle to the peripheral edge of the module structure or it may be in the form of a tape which may be applied to the peripheral edge of the module structure.

A junction box is typically attached on the exposed surface of the back protective sheet, right below the interconnected solar cells, using moisture barrier adhesives. Terminals of the interconnected solar cells are typically connected to the junction box through holes formed in the back protective sheet. In this way, the size of the module can be reduced as the frame holding the cells can be positioned very close to the solar cells. The holes in the back protective sheet must be very carefully sealed against moisture leakages using, for example, potting materials such as silicone, epoxy, butyl, and urethane containing materials. If the seal in the holes fails, such holes allow moisture to enter the module and can cause device failures.

Thin film solar cells are more moisture sensitive than the crystalline Si devices; therefore, materials with moisture barrier characteristics need to be used in the module structure and any potential moisture sources such as holes in the back and front protective sheets are problematic. For a flexible module to last 25 years, all the packaging components are also required to preserve mechanical, thermal, and chemical stability in the outdoors. The front protective sheet for thin film devices can be either glass or a flexible sheet depending on the product design requirements. A flexible front sheet can be composed of a combination of one or more weatherable films, such as fluoropolymers, for example, ETFE (ethylene-tetrafluoroethylene) or FEP (fluoro ethylene propylene) or polyvinylidene fluoride (PVDF) and a transparent inorganic moisture barrier layer such as Al₂O₃ or SiO₂. In one product, a weatherable film (ETFE, FEP or PVDF) can be laminated onto one or more inorganic moisture barrier layers to form a front protective sheet. However, during the lamination, stresses resulting from UV exposure, temperature cycle and humidity can deteriorate the front protective sheet which can result in severe inorganic moisture barrier-layer delaminations from the weatherable films. One can alleviate these problems by first incorporating the inorganic barrier layers onto a carrier film like poly(ethylene teraphthalate) PET and poly(ethylene naphthalate) PEN and then applying the weatherable film onto the carrier film instead of the barrier layer. Such carrier polymers are thermally and mechanically more stable. Although PET and PEN films are not as weatherable as the ETFE and FEP films, any temperature cycling on the solar panel would not impose as much stress as it would on a fluoropolymer like ETFE, FEP.

A further difficulty that presents itself during manufacturing of solar cells is that the placement of the junction box on the solar cell module can vary depending upon the application of the solar cell. In some instances, the junction box is placed on the front surface which results in additional layers being added to the front surface to enhance adherence of the junction box. In other instances, the junction box is mounted on the back surface. In either circumstance, the module is usually custom fabricated for each mounting location which results in reduced manufacturing efficiencies for each different mounting location.

Thus, there is a need for a manner of manufacturing the solar cells that allows for greater efficiencies and still permits flexible mounting locations for the junction boxes. To this end, there is a need for a solar cell module and method of manufacturing the same that allows for a standardized module to be fabricated and laminated and also permits subsequent flexible mounting of the junction boxes in a plurality of different locations.

### SUMMARY

The aforementioned needs are satisfied by the present invention which in one aspect comprises a flexible solar power apparatus comprising a solar power module having a flexible bottom sheet and a flexible top sheet and side sealing regions, wherein the solar power module defines a first edge and an interior space that houses at least one solar cell and wherein the at least one solar cell includes a conductive pathway that allows for current generated by the at least one solar cell to be transmitted outside of the solar power module. In this aspect, the apparatus further comprises a mounting module that is coupled to the first edge of the solar power module adjacent a first side sealing region wherein the mounting module defines a first mounting surface and a second mounting surface proximate the first flexible bottom sheet and the second flexible top sheet respectively of the solar power module. In this aspect the module further comprises a junction box that is mounted on the mounting module, wherein the mounting module is adapted to receive the junction box on either the first or second surfaces and wherein the junction box is electrically coupled with the conductive pathway to receive the current generated by the at least one solar cell.

In another aspect, the invention comprises a method of forming a solar cell, the method comprising forming a solar panel module wherein at least one solar panel is sealed within an enclosure having a first sealed edge and wherein the solar panel module has a conductive pathway that extends through the first sealed edge. The method further comprises forming a junction box module that is configured to receive a junction box in a plurality of different locations and is further configured to be attached to the solar panel adjacent the first sealed edge. The method further comprises attaching the junction box module to the solar panel module and mounting the junction box on one of the plurality of different locations of the junction box module.

These and other objects and advantages will become more apparent from the following description taken in conjunction with the accompanying drawings.

### BRIEF DESCRIPTION OF THE DRAWINGS

FIG. 1 is a schematic view a thin film solar cell;

FIGS. 2A-2C are side views of embodiments of a solar panel assembly after lamination, indicating how a bus ribbon can be extracted from the solar cell and where junction boxes can be mounted on the assembly;

FIG. 3 is a top view of the solar panel assembly of FIG. 2B;

FIG. 4 is a side view of the solar panel assembly of FIG. 2B with an additional mechanical support;

FIG. 5 is a top view of the solar panel assembly of FIG. 4;

FIG. 6 is a side perspective view of another embodiment of a solar panel assembly after lamination having a clamp mounting tab;

FIGS. 7A and B are side perspective views of another embodiment of a solar panel assembly after lamination where the bus ribbon is clamped between two substrates;

FIGS. 8A-8D are top views of different implementations of the solar panel assembly of FIGS. 6 and 7;

FIG. 9A-9B are side views of another embodiment of a solar panel assembly having a mounting tab that can accommodate a junction box on either side;

FIG. 10A-10B are side views of another embodiment of a solar panel assembly having a step-on mounting tab that can receive a junction box on either surface;

FIG. 11A-11B are side views of another embodiment of a solar panel assembly that has the bus ribbon that can be wrapped onto a top or bottom surface to receive a junction box thereon; and

FIG. 12A-12B are side views of another embodiment of a solar panel assembly that has the bus ribbon that can be wrapped onto a top or bottom surface to receive a junction box thereon.

### DETAILED DESCRIPTION OF THE PREFERRED EMBODIMENTS

The preferred embodiments described herein provide methods of manufacturing a flexible photovoltaic power apparatus or solar panel including one or more flexible solar modules employing interconnected thin film solar cells, preferably Group IBIIIAVIA compound solar cells. The photovoltaic power apparatus or solar panel preferably includes a sealed module chamber and various embodiments of mechanisms and methods for attaching a junction box to the solar power module in the module chamber.

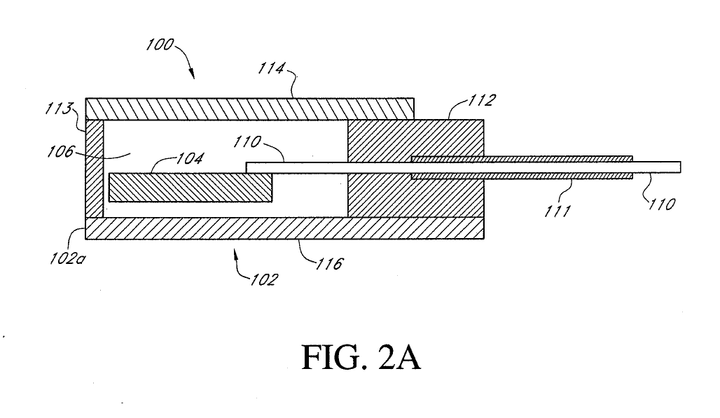

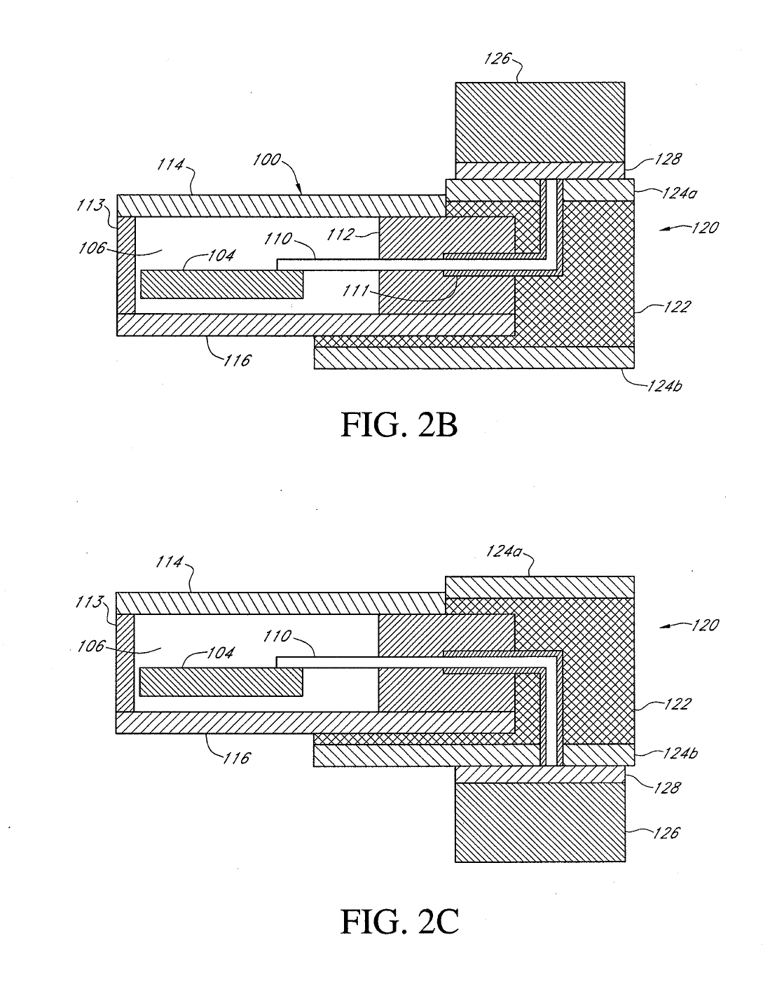

Reference will now be made to the drawings wherein like numerals refer to like parts throughout. FIG. 2A shows a partial side view of an embodiment of a flexible solar panel assembly 100 of the present invention.

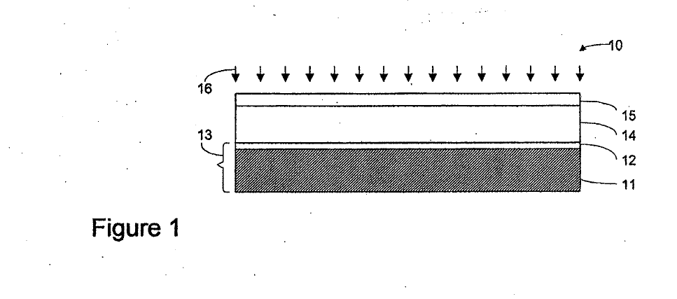

The flexible solar panel assembly 100 may comprise a module 102 having a module housing 102A, that contains thin film solar cells 104 of the type described above in connection with FIG. 1. As shown, the solar cells 104, which may be interconnected to form a circuit, are positioned within the module housing 102A. The module housing may include a front sheet 114 and a back sheet 116 and may be sealed on the edges or the perimeter of the module, by a peripheral sealant wall 112 or edge sealant. The peripheral sealant wall 112 extends about the module 102 and includes a region 112A on the opposite side of the junction box to thereby fully seal the module 102 from moisture intrusion. The solar cells 104 may preferably be encapsulated by an encapsulant layer 106 or encapsulant in the housing 102A Preferred materials for the encapsulant 106 may be ethylene vinyl acetate (EVA), thermoplastic polyurethane (TPU), polysiloxane, polyvinyl butyral, ionomer, thermoplastic polyolefins or some combination thereof. The encapsulant 106 fills the space surrounding the solar cells 104 and is preferably made of a transparent encapsulant material that tightly seals the solar cells 104 and other module structures such as busbars or conductors used to interconnect the solar cell by covering their surfaces.

The front sheet 114 may comprise a top flexible protective sheet formed of a flexible and transparent material. The material may include a polymer such as ethylene tetrafluoroethylene (ETFE) under TEFZEL® commercial name or fluorinated ethylene propylene (FEP) from DuPont or poly vinylidene fluoride (PVDF) under KYNAR commercial name. Alternatively, the front sheet 114 may be a multilayer transparent structure including at least an outer polymeric layer, such as ETFE, FEP or PVDF, covering a transparent inorganic moisture barrier layer such as Al₂O₃ or SiO₂. The back sheet 116 may be a polymeric back sheet material such as TEDLAR, PVDF, PET, perfluoro-alkyl vinyl ether, PA or PMMA.

The solar cells 104 include a number of solar cells 104 interconnected using a stringing technique that employs conductive leads such as conductive wires or ribbons, to electrically connect the solar cells, preferably in series. However, the solar cells 104 may also be formed using shingling techniques to interconnect the solar cells 104 without using conductive leads, such shingling principles are described above in the background section. As shown in FIG. 1, Each solar cell 104 generally includes a substrate 11, an absorber layer 14 formed over the substrate and a transparent layer 15 formed over the absorber layer 11. The absorber layer may be a Group IBIIIAVIA absorber layer such as a Cu(In,Ga) Seₑ compound layer, which is often referred to as CIGS. The substrate may be a flexible foil substrate such as a stainless steel foil or an aluminum foil. There may be a back contact layer 12, such as a molybdenum layer between the substrate and the absorber layer. A current collecting structure (not shown) including a busbar and fingers is deposited onto a top surface of the transparent layer 15, which is also the light receiving side of the solar cells 104.

The module housing 102A further includes the peripheral sealant wall 112 or edge sealant that may comprise either a moisture sealant or an edge tape. If an edge tape is used as the edge seal, the edge tape seals the side walls of the housing 102A and may be made of a moisture barrier sealant tape. The moisture sealant may be of a viscous moisture barrier sealant. An exemplary material for the edge sealant and may be butyl rubber with desiccants having 5 to 13 mm width and 0.5 mm to 1.5 mm thickness.

As is also shown in FIG. 2A, a bus conductor 110 or conductive lead is electrically connected to the solar cells 104 so as to convey the electrical current produced by the solar cells outward of the solar module assembly 100 for subsequent collection and use. The bus conductor 110 may be made of a wire or multiple wires, such as micro wires or a metal strip or a ribbon. The bus conductor 110 may be covered by an insulating film or tubing 111 which can be formed of the following materials: polyethylene terephthalate (PET), which is available under the commercial names Mylar, Melinex, heat shrink. Mylar; polyimide (Kapton); polyolefins (EPS 300); and polyethylene napthalate (PEN).

As is shown in FIG. 2A, the bus conductor 110, which is examplified as a conductive ribbon in this embodiment, extends out through the edge of the panel with the insulating film or tubing 111 being positioned about it. The insulating film or tubing 111 may begin in the middle of the edge sealant 112. The front sheet 114 only extends over a portion of the edge sealant 112 whereas the back sheet 116 extends over the entire edge of the edge sealant 112. The module 100 of FIG. 2A can then be used to interconnect with a junction box mounting module 120 on either the front or back sides of the assembly in the manner shown in FIGS. 2B and 2C respectively. As is illustrated, the module 100 is sealed against moisture intrusion thereby protecting the solar cells 104 positioned therein. The only element that extends outward therefrom may be the bus conductor 110 which is sealed to limit access paths for moisture to enter the module 100. As will be discussed in greater detail below, the various ways of mounting the junction box are preferably accomplished in a manner that preserves the moisture seal integrity of the module 100.

More specifically, referring to FIG. 2B, the junction box mounting module 120 comprises a sealant 122, such as a sealant tape or layer, that is potentially formed of the same material as the edge sealant 112. Mounting pads or layers 124a, 124b, which may be sheet shaped and may be made of the material of the back sheet 116, is then positioned on the upper and lower surfaces of the edge or sealant 122. The back sheet material such as the above mentioned TEDLAR, PVDF, PET, etc., is better suited for mounting a junction box 126 to the assembly 100 because of its moisture barrier properties. If the back sheet material used is non transparent to light, it provides better protection to the underlying materials and protects them from the degradation by exposure to sunlight. As shown in FIGS. 2B and 2C respectively, the junction box 126 can be mounted to either the top or bottom of the module by using a tape or sealant 128 to adhere to mounting pads 124a, 124b made of the back sheet material. The bus conductor 110 extends outward of the module 100 and can then be routed through the sealant 122 and holes can be formed through the mounting pads 124a, 124b to permit the bus conductor 110 to be routed into the junction box 126.

The junction box 126 may be made of Noryl, PPE (poly phenylene ether), PET, Nylon, Polycarbonate, or PPE with PS (poly styrene) materials. Exemplary adhesives or sealant layers 128 that can be used to attach the junction box 126 to the mounting pads 124a, 124b may be silicone sealants such as Dow Corning PV804, Shinetsu KE220/CX220, Tonsan 15276 or adhesive tapes like 3M VHB 5952, Duplomont 9182. The adhesive tapes may need a primer to apply them to the surface materials.

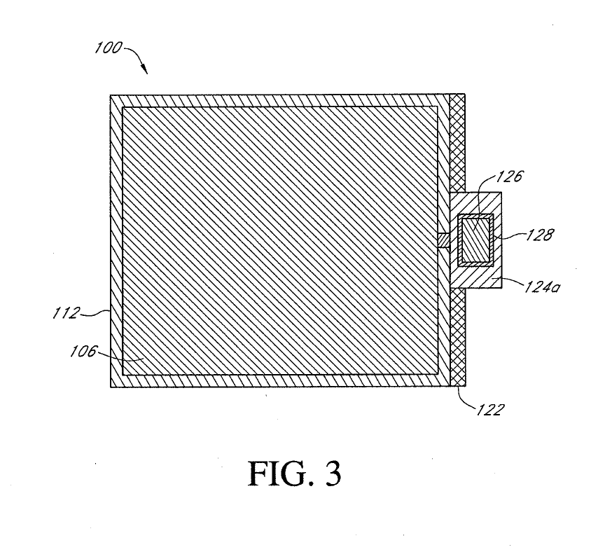

FIG. 3 is a top view of the solar cell assembly 100 illustrated in FIGS. 2A-2C. As shown, the solar cell module 102 has the sealant 122 that extends, in this embodiment, substantially across the width of the module 100. The mounting pads 124 then extend outward from the sealant 122 in only the location of the junction box 126. As illustrated, the junction box 126 is attached to the mounting pads 124 via the sealant 128. The exact size and configuration of the junction box 126, the mounting pads 124 and the sealant 122 can, of course, vary depending upon the implementation.

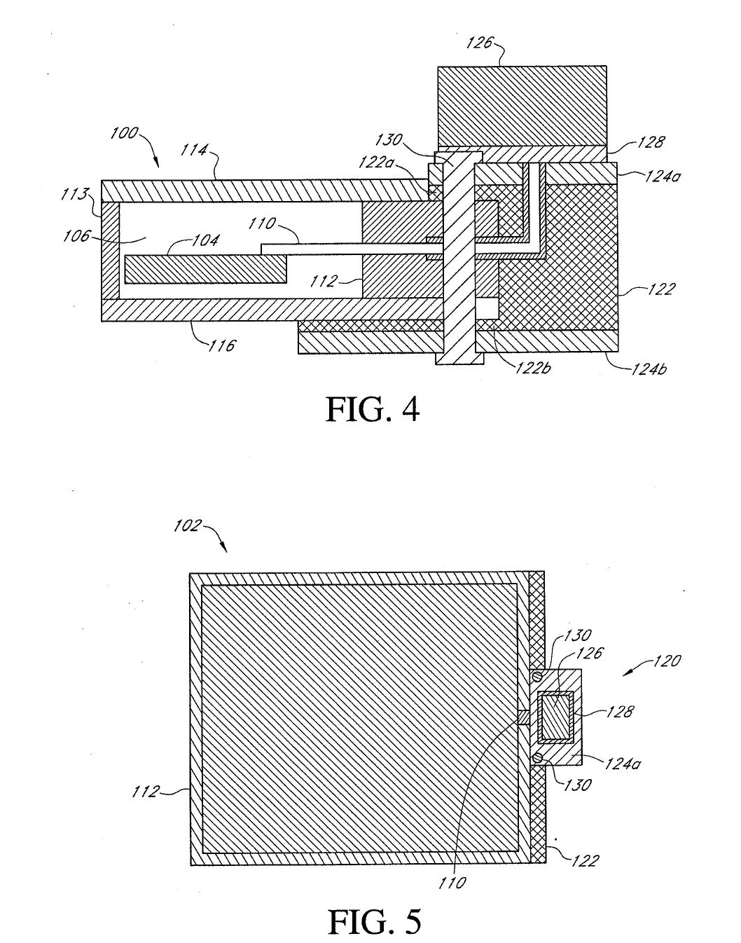

Referring to FIGS. 4 and 5, the attachment of the junction box 126 can be enhanced through the use of mechanical supports 130. The mechanical supports 130 can be in the form of rivets that extend through the pads 124a, 124b, the edge sealant 112, and the portions of the sealant 122a, 122b that are interposed between the back sheet material pads 124a, 124b and the edge sealant 112 and the back sheet 116. In one implementation, support members 130 may be added following the lamination process to provide mechanical support for the module assembly. As shown in FIG. 5, the supports members 130 can be added on either side of the junction box 126 to provide support on either side and to better adhere the junction box 126 to the module 102. As shown, the junction box module 120 mounts to the outer side of the module 100 without affecting or penetrating the sealing components of the module 100. Thus, the moisture barrier integrity of the module 100 is maintained.

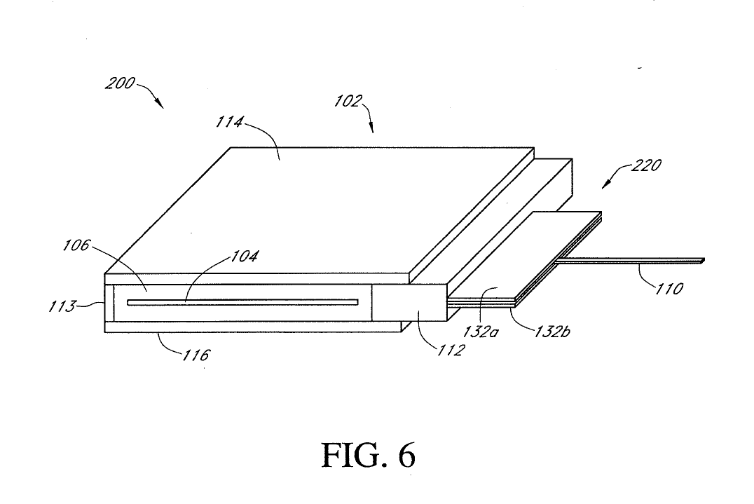

FIG. 6 illustrates another laminated solar cell assembly 200 that discloses another manner in which a junction box can be mounted to the solar cell assembly 200. As shown, a solar cell module 102 that includes the solar cells 104 that is surrounded by an encapsulant 106 and a front sheet 114 and a back sheet 116 is disclosed. The edges of the module 102 can also be sealed by an edge sealant 112 such as an edge sealant tape. The components of the solar cell assembly 200 that define the module 102 are substantially the same as the components described above with respect to the FIGS. 2A-5.

As shown in FIG. 6, a mounting module 220 comprising two cantilevered support members 132a, 132b that extend through the edge sealant 112 where the bus conductor or ribbon 110 is sandwiched between the cantilevered support members 132a, 132b can be attached to the solar module 102. The cantilevered support members 132a, 132b provide a surface upon which a junction box 126 can be mounted on either side depending upon the application. Providing a standard mounting module 220 that can receive a junction box on either side greatly enhances the flexibility of the manufacturing process as the solar modules 102 and mounting modules 220 can be formed in bulk and then adapted to receive the junction boxes as needed by the particular costumer application.

The cantilevered support members 132a, 132b in one implementation are layers or sheets that are preferably formed of an electrical insulator material such as InsulPatch™ or electrical insulator material EPE that is formed of a material that permits the junction box to be adequately adhered to the cantilevered support members 132a, or 132b. EPE material could be made of EVA/PET/EVA layers laminated to each other. Usually Each EVA layer can be 25 um to 250 um thick, and PET layer thickness can also vary from 25 um to 250 um. EVA layers can be replaced by other thermoplastic encapsulants. The same multilayer film can also be made of single layer film such as PET, ETFE, Kynar, Kapton. Upon lamination, the cantilevered support members 132a, 132b are clamped using tapes, hot melt or a dispensable thermoset foam and a window can then be opened on either the front side or the back side of the substrate to receive the junction box.

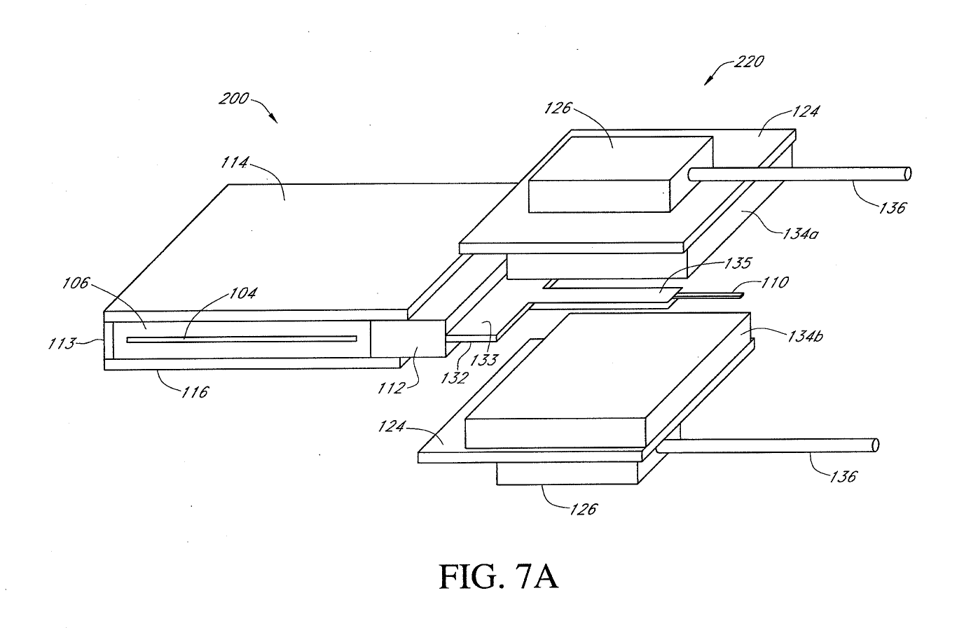

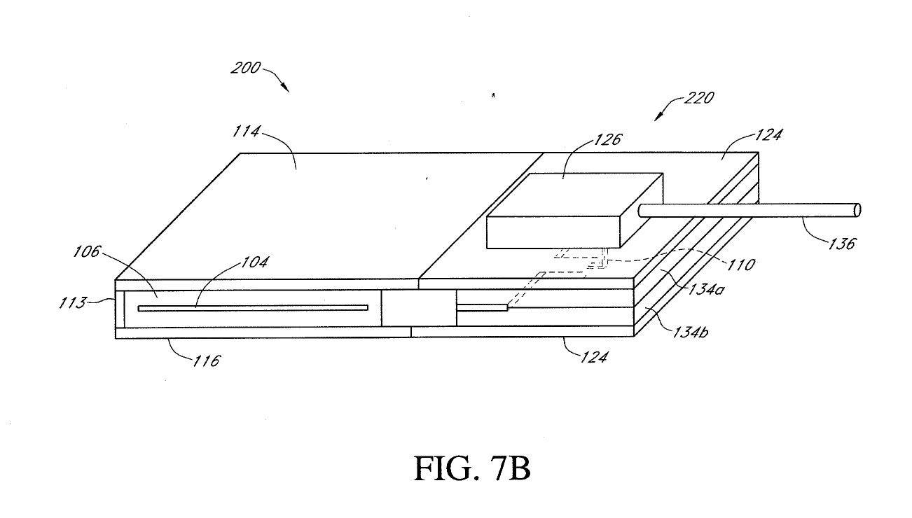

FIGS. 7A and 7B illustrate the manner in which a junction box 126 can be attached to either the front or bottom surface or side of the mounting module 220 shown in FIG. 6. As shown, the cantilevered support members 132a, 132b includes a first region 133 that preferably extends across the width of the module 220 and a narrower region 135 that extends outward from the first region 133 that covers the bus conductor 110. As shown, the narrow region 135 has two layers with the bus conductor 110 interposed therebetween so as to provide protection to the bus conductor 110. An adhering tab 134a or 134b is then mounted on either the upper surface of the cantilevered support members 132a, 132b or the lower surface of the cantilevered support members 132a, 132b. The adhering tabs 134 can also be mounted on both the upper and the lower surfaces the cantilevered support members 132a, 132b. The adhering tab 134a, 134b may preferably be a moisture resistant sealant layer, for example a junction box bonding tape like VHB tape. A layer of back sheet material forming a mounting pad 124 is then mounted on the adhering tab 134a or 134b depending upon whether a front surface or back surface mount of the junction box 126 is desired. The bus conductor may be routed through the adhering tab 134a or 134b and the mounting pad 124 for the junction box connection. Once the location of the junction box is determined and the bus conductor is taken out. The other side of the mounting module is completed by placing another piece of mounting pad 124, or alternatively placing both an adhering tab 134 and mounting pad 124 together. The edge of the mounting module may or may not be sealed using an edge sealant. The junction box 126 is secured to the mounting pad 124 using epoxy, silicone sealant, or tape in the same manner as described above. Thus, the module 102 and the mounting module 220 can be manufactured and laminated in one manufacturing process and these modules can then be used to make two different types of solar cells depending upon where the junction box 126 is desired to be mounted. Once the junction box 126 is mounted, a conductor 136 can then interconnect the junction box 126 to other solar modules or to a power circuit in a manner well known in the art.

As is shown in FIG. 7B, the junction box 126 is positioned on the top and the bus conductor 110 is routed to the junction box 126 through the adhering tab 134a and the mounting pad 124. As shown, the bus conductor 110 may be sandwiched between the upper adhering tabs 134a and 134b. Again, the module 220 for mounting the junction box 126 to the solar cell module 200 attached to the peripheral surfaces of the module 200 which further enhances the moisture integrity of the module 200.

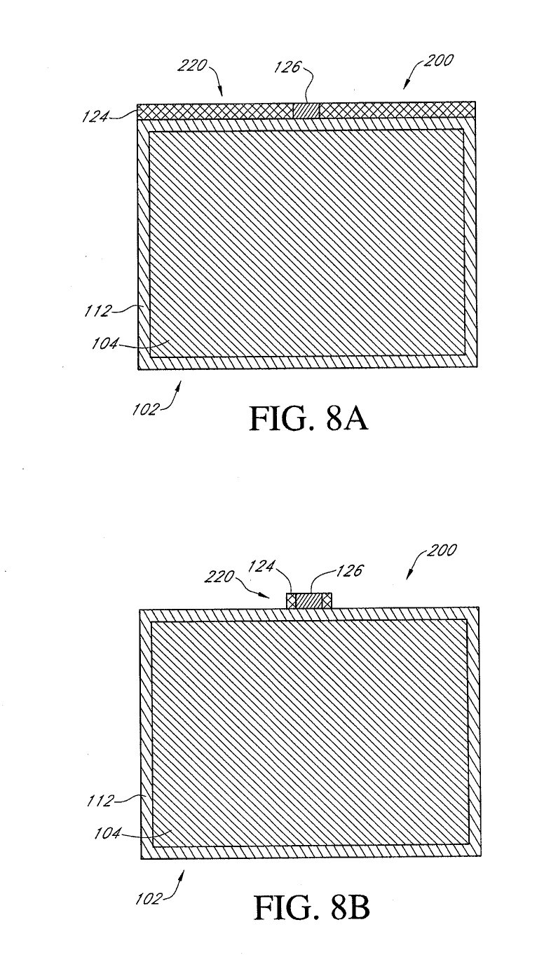

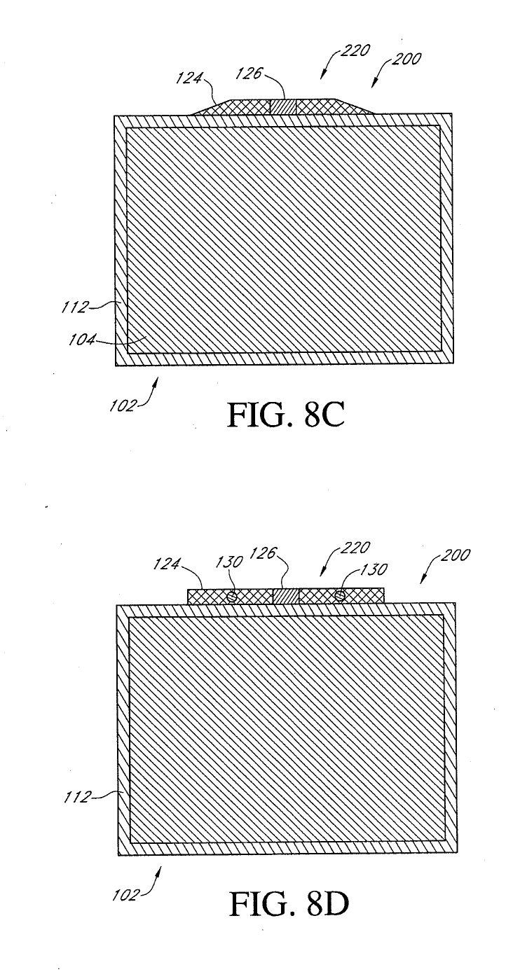

FIGS. 8A-8D illustrate that the configuration of the module 220 and a mounting pad 124 can vary depending upon the implementation without departing from the spirit of the present invention. In some instances, the solar panel assembly 200 may be used in environments where the module 220 may be subjected to larger mechanical forces and the mounting pad 124 can extend across the entire width of the solar cell module 102 as is shown in FIG. 8A. Alternatively, to conserve materials the module 220 and the mounting pad 124 in other implementations may be sized so as to accommodate the junction box 126 as is shown in FIG. 8B. The degree of attachment of the module 102 and the mounting tab is thus variable as is the configuration. For example, the mounting pad 124 may have tapered corners as is shown in FIG. 8C and mechanical supports 130 such as rivets shown in FIG. 8D may also be used to enhance the interconnection of the mounting module, the mounting pad 124 to the solar cell module 102. It will be understood that the exact configuration of the mounting pad 124 and its interconnection to the module 102 will be dependent upon the intended use of the solar cell 100, the size of the junction box 126 and other related considerations.

The foregoing description of a mounting module 220 having a mounting pad 124 for mounting a junction box 126 has been described in conjunction with a system that uses edge sealant 112 such as an edge tape. However, it will be appreciated that the same type of mounting method can also be used in conjunction with module 102 that don't use edge sealant 112. In those implementations, an encapsulant 106 will cover the panel footprint and the bus conductor 110 or ribbon may extend out of the encapsulant 106 and the bus conductor 110 may then be embedded between an insulating film like EPE and the encapsulant 106 may extend outward from the main body of the module the same amount as the insulating film. The mounting pad 124 can then be mounted on the encapsulant and the insulating film.

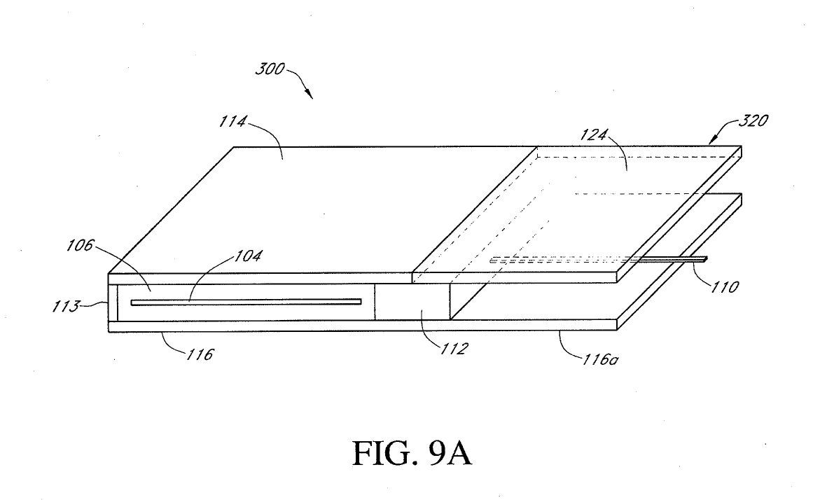

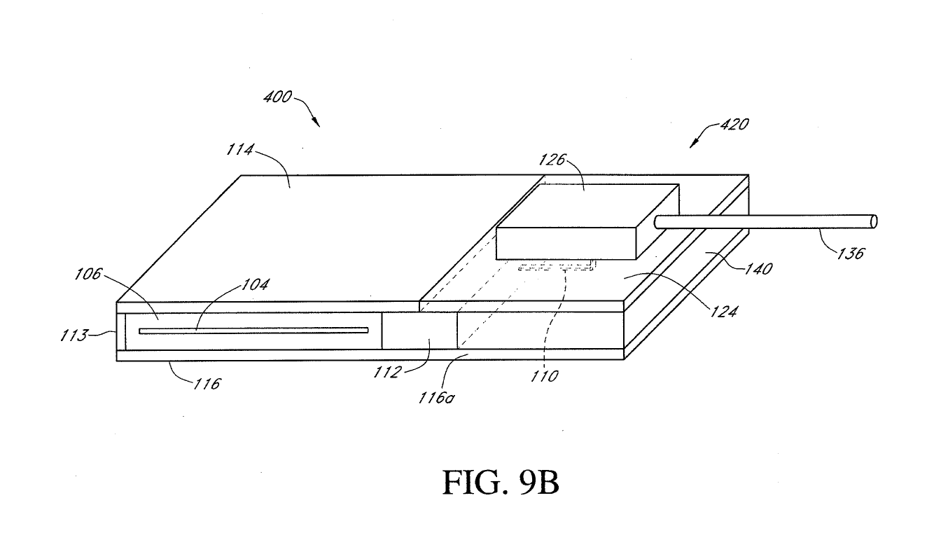

FIGS. 9A and 9B illustrate another mounting module 320 that can be prefabricated for use with both upper or lower surface mounting of junction boxes 126. In this implementation, an assembly 300 is manufactured that has a solar cell module 102 that has a solar cell 104 positioned within encapsulant layers 106. The encapsulant layers 106 are then interposed between a front sheet 114 and a back sheet 116 in the manner described above. The edges are then sealed using an edge sealant 112 in substantially the same manner as described above.

As shown in FIG. 9A, however, the back sheet layer 116 extends beyond the edge sealant 112 so as to define a cantilevered section 116a which is a portion of a mounting module 320. A mounting pad 124, preferably formed of the material of the back sheet 116 can then be positioned adjacent the front sheet 114 so as to extend outward from the edge sealant 112 in a cantilevered fashion to form part of the mounting module 320. The bus conductor 110 then extends out of the edge sealant 112 so as to be interposed between the mounting pad 124 and the cantilevered section 116a of the back sheet 116.

This configuration also permits mounting of junction boxes 126 on either the mounting pad 124 adjacent the front sheet 114 or adjacent the back sheet 116 depending upon the desired implementation. As shown in FIG. 9B, the junction box 126 can be mounted as desired and the bus conductor 110 then bent to extend into the junction box 126 through openings formed in either the cantilevered section 116a or the mounting pad 124 in a known manner. The gap between the cantilevered section 116a and the mounting pad 124 can then be sealed using an insert member 140 which can comprise an insert tape, a hot melt, a thermosetting foam or something equivalent that seals the space and protects the conductive bus conductor 110 from shorts and environmental contamination. Again, this mounting module 320 mounts to the periphery of the module 300 which maintains the moisture tight integrity of the module 300 while permitting flexible mounting of the junction box 126 on either the top or the bottom surface.

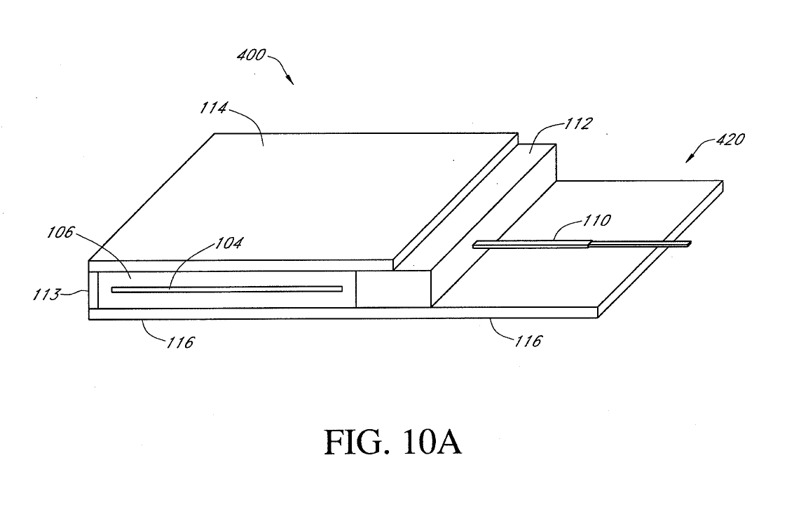

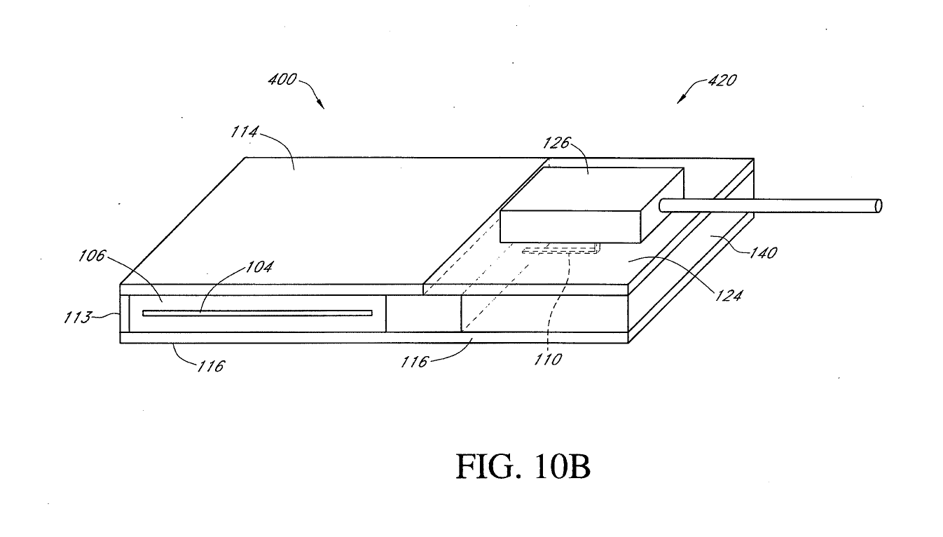

FIGS. 10A and 10B illustrate another assembly 400 very similar to the assembly 300 described above in conjunction with FIGS. 9A and 9B. In this implementation, a portion of the back sheet 116 extends beyond the edge sealant 112 so as to define the cantilevered section 116a that is part of a mounting module 420. If a back mounted junction box 126 is described, an insert member 140 like those described above is positioned on the cantilevered section 116a to cover the bus conductor 110 and the junction box 126 is mounted on the cantilevered section 116a opposite the insert member 140 in the manner shown in FIG. 10b. Alternatively, if a top mounted junction box 126 is desired, then the mounting pad 124 with the junction box 126 formed thereon can then be mounted and the insert member 140 can then be used to fill the gap in the manner described above. Thus, the embodiments of FIGS. 9A, 9B and 10A, 10B can both be manufactured ahead of time and then adapted to the desired mounting configuration for the junction box 126.

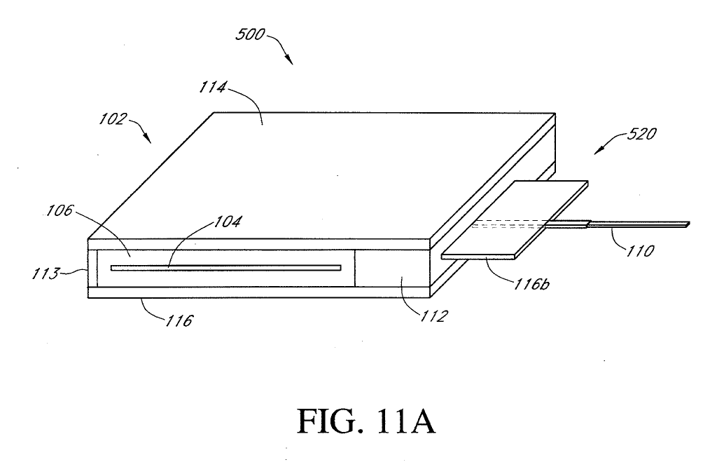

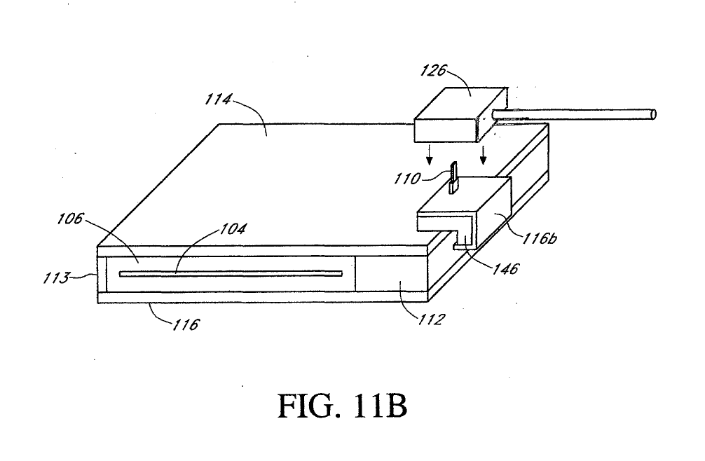

FIGS. 11A and 11B illustrate yet another embodiment of an assembly 500 that can be used in conjunction with both top or bottom mounted junction boxes 126. In this implementation, the module 102 includes a solar cell module 102 that has a solar cell 104 that is positioned between encapsulant layers 106 which are interposed between a front sheet 114 and a back sheet 116 in substantially the same manner as described above. The edge of the back sheet 116 and front sheet 114 are sealed with edge sealant 112 or an equivalent. The bus conductor 110 is positioned on top of an extended member 116b that extends outward from the edge sealant 112 and forms part of a mounting module 520. The extended member 116b may be made of a piece of the material of the back sheet 116. A release liner can be used to protect the bus conductor 110 during the lamination process.

As shown in FIG. 11B, the extended member 116b can then be bent to either the top sheet 114 or to the bottom sheet 116 as desired and provide a mounting surface for the junction box 126. The extended member 116b can be secured to the top sheet 114 or the back sheet 116 using a mounting member 142 which can comprise a hot melt, a pressure sensitive tape or a dispensable thermoset foam. Again, the mounting module 520 provides a basic module that can be used for either a top or bottom mounted junction box.

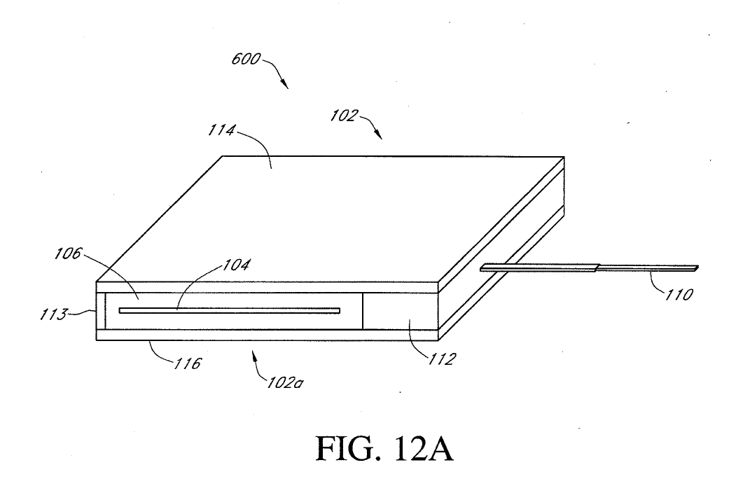

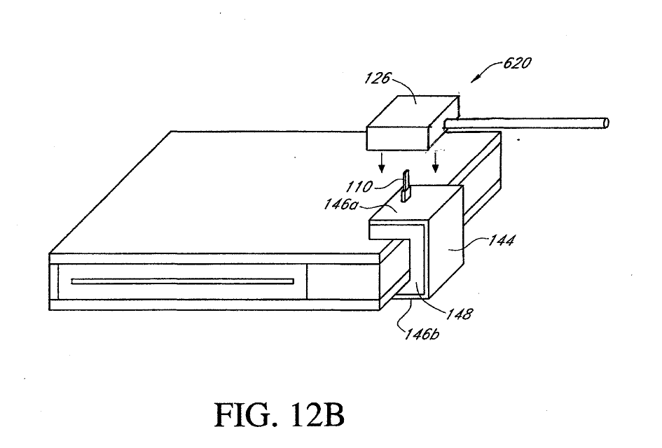

FIGS. 12A and 12B illustrate yet another assembly 600 that can be formed and adapted for use with both a top or bottom mounted junction box 126. In this implementation, the module 102 includes a solar cell 104 that is sandwiched between two encapsulant layers 106 and the top sheet 114 and back sheet 116 as described above. The edge of the module 102 is sealed with the edge sealant 112 in the above-described manner with the bus conductor 110 extending outwardly therefrom in substantially the center of the edge sealant 112. A two sided wrapped mounting tab 144 that forms a mounting module 620 formed in one implementation of the same material as the back sheet is then formed. As shown in FIG. 12B, the two sided wrapped mounting tab 144 has a C-shape with an upper surface 146a that mounts to the top sheet 114 and a bottom surface 146b that mounts to the bottom sheet 116. The two sided wrapped mounting tab 144 is secured to the edge of the module 102 using hot melt, dispensable thermoset foam or tape 148 in the manner described above and the bus conductor 110 can then be routed through an opening formed in the upper or lower surface 146a, 146b of the two sided mounting member 144 to thereby be connected to the junction box 126.

Again, the embodiment of FIGS. 12A and 12B allows for a single module to be made that can accommodate junction boxes mounted on either the top surface or the bottom surface and this mounting can be accomplished without affecting the moisture integrity of the module containing the solar cells 104. Manufacturing efficiencies can be gained by manufacturing a single module that can be readily adapted for different mounting locations of junction boxes as opposed to custom manufacturing a module for a specific junction box mounting location.

Although aspects and advantages of the present inventions are described herein with respect to certain preferred embodiments, modifications of the preferred embodiments will be apparent to those skilled in the art. The scope of the present invention should not be limited to the foregoing discussion but should be defined by the appended claims.

We claim:

1. A flexible solar power apparatus comprising:
a solar power module having a flexible bottom sheet and a flexible top sheet and side sealing regions, wherein the solar power module defines a first edge and an interior space that houses at least one solar cell and wherein the at least one solar cell includes a conductive pathway that allows for current generated by the at least one solar cell to be transmitted outside of the solar power module;
a mounting module that is coupled to the first edge of the solar power module adjacent a first side sealing region wherein the mounting module defines a first mounting surface and a second mounting surface proximate the first flexible bottom sheet and the second flexible top sheet respectively of the solar power module; and
a junction box that is mounted on the mounting module, wherein the mounting module is adapted to receive the junction box on either the first or second surfaces and wherein the junction box is electrically coupled with the conductive pathway to receive the current generated by the at least one solar cell.

2. The apparatus of claim 1, wherein the flexible bottom sheet includes a first material and the flexible top sheet includes a second material that is transparent to visible light.

3. The apparatus of claim 2, wherein the solar power module includes an encapsulant material coating the at least one solar cell and filling the interior space of the solar cell module.

4. The apparatus of claim 3, wherein the flexible bottom sheet include a polymeric outer layer covering an inorganic non-transparent moisture barrier layer.

5. The apparatus of claim 1, wherein the at least one solar cell includes at least one Group IBIIIAVIA thin film solar cell.

6. The apparatus of claim 1, wherein the flexible top sheet comprises a sheet of flexible glass.

7. The apparatus of claim 1, wherein the mounting module comprises an edge sealant portion having a first and a second surface wherein the edge sealant portion is attached to the first edge of the solar power module and the first and second surfaces of the edge sealant portion are adapted to receive the junction box.

8. The apparatus of claim 7, wherein the flexible top sheet does not extend to the edge of the first side sealing region so as to expose a surface of the first side sealing region and wherein the flexible top sheet extends to the edge of the first side sealing region.

9. The apparatus of claim 8, wherein the mounting module is adhered to the flexible bottom sheet and to the exposed surface of the first side sealing region.

10. The apparatus of claim 7, wherein the first and second mounting surfaces are comprised of the same material that forms the flexible bottom sheet.

11. The apparatus of claim 7, wherein the edge sealant portion extends along the width of the first edge of the solar power module.

12. The apparatus of claim 7, further comprising at least one mechanical support that extends between the first and second mounting surface and through the first side sealing region of the solar power module to mechanically couple the mounting module to the solar power module.

13. The apparatus of claim 1, wherein the mounting module comprises first and second cantilevered members that extend outward from the first side sealing region of the solar power module wherein the conductive pathway is positioned between the first and second cantilevered members.

14. The apparatus of claim 13, wherein the first and second cantilevered members are formed of an electrically insulating material.

15. The apparatus of claim 13, wherein the mounting module further comprises a first and second mounting tab that defines a first and second surface respectively, wherein the first and second mounting tabs are mounted adjacent the first and second cantilevered members so as to cover the first and second cantilevered members and wherein the junction box is mounted on either the first or second surfaces of the mounting tabs and the conductive pathway is routed through the first or second mounting tabs.

16. The apparatus of claim 15 wherein the first and second surfaces of the mounting tabs include a layer of the material that is the same material as the flexible back sheet that receives the junction box.

17. The apparatus of claim 15, wherein the first and second mounting tabs extend substantially across the width of the first edge of the solar power module.

18. The apparatus of claim 15, wherein the first and second mounting tabs extend across only a portion of the width of the first edge of the solar power module.

19. The apparatus of claim 15, wherein the first and second mounting tabs are tapered.

20. The apparatus of claim 15, further comprising mechanical supports that extend through the first and second mounting tabs.

21. The apparatus of claim 1, wherein the mounting module comprises first and second mounting tabs either of which can receive the junction box that are attached to the first side sealing region of the solar power module so as to extend outwardly therefrom and define a space therebetween, wherein the conductive lead extends out of the first side sealing region in the space.

22. The apparatus of claim 21, wherein the first and second mounting tabs are positioned so as to be substantially co-planar with the flexible bottom sheet and the flexible top sheet respectively.

23. The apparatus of claim 22, wherein the flexible bottom sheet extends beyond the first side sealing region of the solar power module so as to define the first mounting tab of the mounting module.

24. The apparatus of claim 23, wherein the second flexible top sheet does not extend beyond the first side sealing region of the solar power module so as to expose a portion of the first side sealing region of the solar power module and wherein the second mounting tab is mounted to the exposed portion of the side first sealing region.

25. The apparatus of claim 21, further comprising an insert portion that is positioned within the space so as to seal the conductive lead in the space and wherein the conductive lead is routed though the first or the second mounting tabs into the junction box positioned thereon.

26. The apparatus of claim 1, wherein the mounting module comprises a first mounting tab that can receive the junction box that is attached to the first side sealing region so as to extend outwardly therefrom and so as to be positioned proximate the flexible bottom sheet wherein the conductive lead extends out of the first side sealing region in a space above the first mounting tab.

27. The apparatus of claim 21, wherein the first tab is positioned so as to be substantially co-planar with the flexible bottom sheet and wherein the junction box is mounted on the first mounting tab.

28. The apparatus of claim 27, further comprising a cover member that covers the portion of the conductive lead that is in the space wherein the conductive lead is routed from the space through the mounting tab to the junction box positioned on the first mounting tab.

29. The apparatus of claim 26, further comprising a second mounting tab that is positioned on the first side sealing region so as to extend outward from the first edge of the solar power module adjacent the flexible top sheet and wherein the junction box is formed on the second mounting tab.

30. The apparatus of claim 1, wherein the mounting module comprises a first member that extends outward from the first side sealing region wherein the conductive lead is positioned within the first member and wherein the first member is foldable so as to be folded onto either the flexible back sheet or the flexible top sheet of the solar power module so as to define a mounting surface upon which the junction box is mounted.

31. The apparatus of claim 30, further comprising an adhering member that adheres the first member to the flexible bottom sheet or the flexible top sheet.

32. The apparatus of claim 30, wherein the first member is formed of the same material as the flexible bottom sheet.

33. The apparatus of claim 1, wherein the mounting module comprises a clamp member that defines a first and a second surface, wherein the claim member is attached to the first edge of the solar power module so that the first surface is proximate the flexible bottom sheet of the solar power module and so that the second surface is proximate the flexible top sheet of the solar power module and wherein the junction box is mounted on either the first or second surface of the clamp member.

34. The apparatus of claim 33, wherein the portion of the clamp member that defines the first and second surfaces is formed of the same material as the flexible bottom sheet of the solar power module.

35. The apparatus of claim 34, further comprising an adhering member that adheres the clamp member to the solar power module.

36. The apparatus of claim 1, wherein the conductive pathway comprises a conductive lead that extends out of the first side sealing region and is routed into the junction box.

37. A method of forming a solar cell, the method comprising:
forming a solar panel module wherein at least one solar panel is sealed within an enclosure having a first sealed edge and wherein the solar panel module has a conductive pathway that extends through the first sealed edge;
forming a junction box module that is configured to receive a junction box in a plurality of different locations and is further configured to be attached to the solar panel adjacent the first sealed edge;
attaching the junction box module to the solar panel module;
mounting the junction box on one of the plurality of different locations of the junction box module.

38. The method of claim 37, further comprising electrically connecting the conductive pathway to the junction box.

39. The method of claim 37 wherein electrically connecting the conductive pathway to the junction box comprises coupling a conductive lead that extends out of the solar panel module to the junction box.

40. The method of claim 37, wherein forming a junction box module comprises forming a module having an upper and lower surfaces where both are configured to receive the junction box wherein the module is sized so as to couple to peripheral surfaces of the solar panel module.

41. The method of claim 40, wherein forming the solar panel module comprises forming a solar panel module having a flexible bottom sheet and a flexible top sheet and side sealing regions interconnecting the flexible top sheet and the flexible bottom sheet that define a first side sealing region.

42. The method of claim 41, wherein forming a junction box module comprises forming an edge sealant portion having a first and second surface that is adapted to receive the junction box and wherein attaching the junction box to the solar panel module comprises attaching the edge sealant portion to the first side sealing region.

43. The method of claim 42, wherein forming the solar panel module comprises forming the module so that the flexible top sheet does not extend to the edge of the first side sealing region so as to expose a surface of the first side sealing region and wherein the flexible top sheet extends to the edge of the first side sealing region.

44. The method of claim 43, wherein attaching the junction box module comprises attaching the junction box module so that the junction box module is adhered to the flexible bottom sheet and to the exposed surface of the first side sealing region.

45. The method of claim 40, further comprising coupling reinforcing members to the junction box module.

46. The method of claim 40, wherein forming the junction box module comprises forming a module having a first and a second cantilevered member that extend outward from the first side sealing region of the solar panel module and so that a conductive pathway extends between the first and second cantilevered members.

47. The method of claim 46, wherein the first and second cantilevered members are formed of an electrically insulating material.

48. The method of claim 46, wherein forming the junction box module further comprises mounting a first and second mounting tabs that defines a first and second surfaces respectively on the first and second cantilevered members so as to cover the first and second cantilevered members and wherein mounting the junction box comprises mounting the junction box on the first or second surfaces of the mounting tabs.

49. The method of claim 48, wherein the first and second mounting tabs are formed of the same material as the flexible back sheet.

50. The method of claim 40, wherein forming the junction box module comprises forming first and second tabs either of which can receive the junction box and wherein attaching the junction box module to the solar power module comprises attaching the first and second mounting tabs to the first side sealing region so that the tabs extends outwardly therefrom and define a space therebetween so that a conductor lead can be positioned within the space.

51. the method of claim 50, wherein the first and second tabs are substantially co-planar with the flexible bottom sheet and the flexible top sheet respectively.

52. The method of claim 51, wherein forming the first tab comprises extending the flexible bottom sheet beyond the first side sealing region to define the first tab.

53. The method of claim 40, wherein forming the junction box module comprises attaching a first mounting tab to the first side sealing region proximate the flexible bottom sheet so that a conductive tab extends out of the first side sealing region in a space above the first mounting tab and positioning a cover member on the first mounting tab so as to cover the conductive lead.

54. The method of claim 53, wherein forming the junction box module further comprises forming a second mounting tab that is positioned on the first side sealing region so as to extend outward from the first edge of the solar power module adjacent the flexible top sheet.

55. The method of claim 40, wherein forming the junction box module and attaching the junction box module to the solar power module comprises attaching a foldable member that has a conductive lead positioned therein and then folding the foldable member onto either the flexible back sheet or the flexible top sheet so as to define a mounting surface upon which the junction box is mounted.

56. The method of claim 40, wherein forming the junction box module comprises forming a clamp member that defines a first and second surface that can receive the junction box and wherein attaching the junction box module comprises attaching the clamp member to the solar power module so that the first surface is proximate the flexible bottom member and the second surface is proximate the flexible top member.
